(19) United States
(12) Patent Application Publication
(10) Pub. No.: US 2014/0166103 A1
(43) Pub. Date: Jun. 19, 2014

(54) Broadband Metamaterial Absorbers

(71) Applicant: The Trustees of Boston College, Chestnut Hill, MA (US)

(72) Inventors: Krzysztof J. Kempa, Chestnut Hill, MA (US); Zhifeng Ren, Houston, TX (US); Yang Wang, Guangzhou (CN)

(73) Assignee: The Trustees of Boston College, Chestnut Hill, MA (US)

(21) Appl. No.: 14/134,383

(22) Filed: Dec. 19, 2013

Related U.S. Application Data
(60) Provisional application No. 61/739,377, filed on Dec. 19, 2012.

(51) Int. Cl. H01L 31/0216; H01L 31/18

(52) U.S. Cl. CPC H01L 31/02167; H01L 31/18
USPC 136/256; 438/98

(57) ABSTRACT

Broadband metamaterial absorbers are disclosed. In some embodiments, a photovoltaic cell includes a light absorbing layer capable of absorbing solar energy and converting the absorbed energy into electrical current; a perforated conductive film disposed on a light absorbing surface of the light absorbing layer, the conductive film being configured to increase light absorption in the light absorbing layer; and a rear electrode disposed on a surface of the absorbing layer opposite to the light absorbing surface of the light absorbing layer, wherein the rear electrode and the conductive film are in electrical communication with the absorbing layer to collect electrical current generated in the light absorbing material.

### RELATED APPLICATIONS

This application claims the benefit of and priority to U.S. Provisional Application No. 61/739,377, filed on Dec. 19, 2012, which is incorporated herein by reference in its entirety.

### FIELD

The embodiments disclosed herein relate to broadband metamaterial absorbers.

### BACKGROUND

Amorphous silicon (a-Si) solar cells have experienced a remarkable progress with stable energy conversion efficiencies exceeding 10% and very low manufacturing costs. However, while the leading solar technology based on crystalline silicon (c-Si) provides efficiencies approaching the theoretical limit of about 30%, the a-Si cells are still about a factor of two less efficient than their respective theoretical efficiency limit (about 25%). The challenge is to improve the efficiency of the a-Si solar cells in order to fully exploit their advantages in lowering manufacturing costs, and thus dramatically improve the outlook of this environmentally friendly solar energy technology.

The main problem with a-Si in this context is that the p-i-n junctions need to be thinner than the very short carrier mean-free path (<100 nm). Thin a-Si junctions are also desirable to eliminate the deleterious light degradation (the Staebler-Wronski effect), which may plague the conventional a-Si solar cells. However, thin junctions make it difficult to trap light, as the mean-free path of photons in the red part of the spectrum in a-Si is >1000 nm.

What is needed is a highly efficient light trapping scheme which would allow for an increased efficiency in very thin and planar semiconductor absorbers.

### SUMMARY

Broadband absorbers are disclosed herein. According to some aspects illustrated herein, there is provided a photovoltaic cell that includes a light absorbing layer capable of absorbing solar energy and converting the absorbed energy into electrical current; a perforated conductive film disposed on a light absorbing surface of the light absorbing layer, the conductive film being configured to increase light absorption in the light absorbing layer; and a rear electrode disposed on a surface of the absorbing layer opposite to the light absorbing surface of the light absorbing layer, wherein the rear electrode and the conductive film are in electrical communication with the absorbing layer to collect electrical current generated in the light absorbing material.

According to some aspects illustrated herein, there is provided an absorbing layer for a solar cell that includes a light absorbing layer capable of absorbing solar energy and converting the absorbed energy into electrical current; and a perforated conductive film disposed on a light absorbing surface of the light absorbing layer, the conductive film being configured to increase light absorption in the light absorbing layer.

According to some aspects illustrated herein, there is provided a method for forming a solar cell that includes positioning a perforated conductive film disposed on a light absorbing surface of a light absorbing layer, wherein the light absorbing layer is capable of absorbing solar energy and converting the absorbed energy into electrical current and the conductive film is configured to increase light absorption in the light absorbing layer; disposing a rear electrode on a surface of the absorbing layer opposite to the light absorbing surface of the light absorbing layer; and configuring the rear electrode and the perforated conductive film to collect electrical current generated in the light absorbing layer.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 illustrates an embodiment solar cell including a metamaterial effective layer of the present disclosure.

FIG. 2 and FIG. 3 illustrate graphs of absorbance as a function of wave length for materials with various metamaterial dielectric constants and magnetic susceptibility.

FIG. 4A, FIG. 4B and FIG. 4C illustrate various embodiments of a perforated metallic film layer of the present disclosure.

FIG. 5A, FIG. 5B and FIG. 5C present an embodiment solar cell structure, its effective medium model, and the vector model of the reflection coefficients in the complex plane, respectively.

FIG. 6A, FIG. 6B, FIG. 6C, and FIG. 6D present the total reflectance R₃=r₃r₃* vs. normalized frequency Ω=ω/ω₀=6 μm/λ,

FIG. 7A and FIG. 7B present embodiments of a conductive film with periodic structures evolving from islands to perforations.

FIG. 7C illustrates an in-plane unit cell of an optimized checkerboard super-absorber structure, having the following parameters: substrate (Ag: 50 nm), absorber (a-Si: 15 nm), NPMF (Ag: 20 nm, a=280 nm, W=145 nm), IF (ITO: 55 nm).

FIG. 7D presents a color-encoded map of R vs. W and λ.

FIG. 7E presents a graph of R vs. λ (bold-solid black line) simulated for the structure of FIG. 7C, and various modifications of this structure: without IF (thin-solid line), without NPMF (dashed-dotted line), without IF and NPMF (dotted line). A result for the structure of FIG. 7C, but with a=750 nm and W=390 nm (dashed-bold line).

FIG. 7F presents a graph of the total absorbance of the structure of FIG. 7C, and the partial absorbances in the absorber, silver substrate, and NPMF (marked by arrows).

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The present disclosure provides a solar cells comprising an absorbing layer topped with a conductive, perforated metallic layer, such as, for example, a mesh-like network formed from a plurality of nanoparticles in electric communication with one another or a continuous sheet of metal with perforations. In some embodiments, such solar cells can be can highly absorbent (super-absorbent) of electromagnetic radiation in the entire visible range. The perforated metallic film and the absorbing layer in this broadband super-absorber form a metamaterial effective layer, which may negatively refract light in a broad frequency range. In some embodiments, the super-absorption bandwidth can be altered by varying the design of the metallic film. In some embodiments, the metallic film of the present disclosure has a checkerboard pattern of the perforations. In some embodiments, the energy conversion efficiency of a single junction amorphous silicon solar cell having an ultra-thin semiconducting layer topped with a nanoscopically perforated metallic film can exceed 12%.

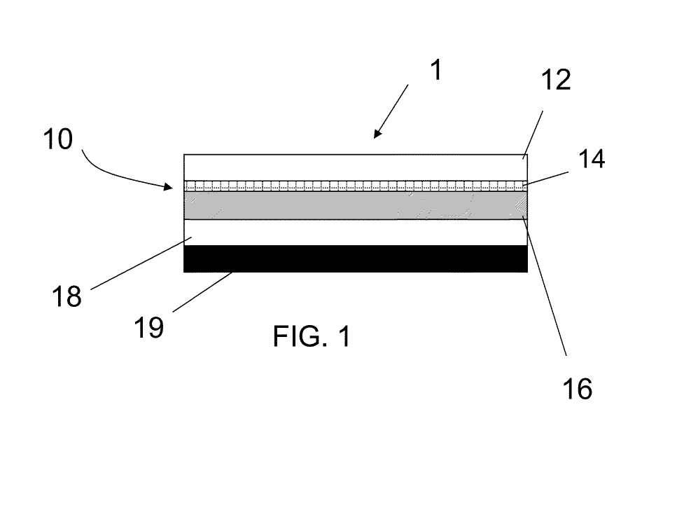

In reference to FIG. 1, a metamaterial effective layer 10 of the present disclosure includes a perforated metallic film (PMF) layer 14 and an absorbing layer 16. In some embodiments, the metamaterial effective layer 10 may be used in manufacturing a solar cell 1, where the PMF layer may serve as a window electrode of the solar cell, that is, the electrode through which the light enters the solar cell.

In some embodiments, the absorbing layer 16 is capable of absorbing solar energy and converting the absorbed energy into electrical current. In some embodiments, the absorbing layer is a semiconductor or photovoltaic junction. In some embodiments, the absorbing layer is a p-n junction. In some embodiments, the absorbing layer is a p-i-n junction. In some embodiments, the PMF layer 14 is deposited over the p-doped side of a p-n junction or a p-i-n junction. In some embodiments, the PMF layer 14 is deposited over the n-doped side of a p-n junction or a p-i-n junction. In some embodiments, the absorbing layer 16 is selected from semiconductor materials, including, without limitations, group IV semiconductor materials, such as amorphous silicon, hydrogenated amorphous silicon, crystalline silicon (e.g., microcrystalline silicon or polycrystalline silicon), and germanium, group III-V semiconductor materials, such as gallium arsenide and indium phosphide, group II-VI semiconductor materials, such as cadmium selenide and cadmium telluride, chalcogen semiconductor materials, such as copper indium selenide (CIS) and copper indium gallium selenide (CIGS). In some embodiments, the absorbing layer 16 is made of a material having a refractive index of greater than 3. In some embodiments, the absorbing layer 16 is made of a material having a refractive index of greater than 4.

By way of a non-limiting example, the absorbing layer 16 is a thin photovoltaic junction of an amorphous silicon (a-Si). In some embodiments, the absorbing layer 16 is a thin p-i-n junction of an amorphous silicon (a-Si). As used herein, the term “thin photovoltaic junction” refers to photovoltaic junctions or photovoltaic films (which terms may be used interchangeably throughout the instant application) having an overall junction thickness between about 1 nanometer (nm) to about 1000 nm. In some embodiments, a thin photovoltaic junction of the present disclosure has an overall junction thickness between about 10 nm to about 310 nm. In some embodiments, a thin photovoltaic junction of the present disclosure has an overall junction thickness between about 10 nm to about 40 nm. In some embodiments, a thin photovoltaic junction of the present disclosure has an overall junction thickness between about 15 nm to about 30 nm. In some embodiments, a thin photovoltaic junction of the present disclosure has an overall junction thickness of about 40 nm. In some embodiments, a thin photovoltaic junction of the present disclosure has an overall junction thickness of about 15 nm.

In some embodiments, the PMF layer 14 can be a geometrically patterned metallic sheet. In some embodiments, the PMF layer 14 is made of a conductive metal to allow the PMF layer 14 to act as a solar cell electrode. In some embodiments, the thickness of the PMF layer 14 is less than 100 nm. In some embodiments, the thickness of the PMF layer 14 is less than 50 nm. In some embodiments, the thickness of the PMF layer 14 is less than 500 nm. Suitable metals include, but are not limited to, silver (Ag), copper (Cu), gold (Au), properly corrosion protected alkali metals, such as aluminum (Al), sodium (Na), potassium (K), etc., among many similar metal. In some embodiments, the thickness of the PMF layer 14 is subwavelength. In some embodiments, the deposition of the metallic film can be accomplished by either the nanosphere lithography, nano-imprint lithography or even spray coating as well as other metal deposition methods

In some embodiments, tuning the geometry of the PMF layer 14 provides the controls to tune the light absorption by the metamaterial effective layer 10 of the present disclosure. When an electromagnetic wave with a certain frequency w enters the metamaterial effective layer of the present disclosure, the total energy budget can be summarized as T(ω)+R(ω)+A(ω)=1, where T is the transmissivity, R is the reflectivity, and A is the absorptivity. In the context of solar cells, one goal is to maximize the absorption of energy. In the absorbing layer 16: A_{PV}(ω)=1−T(ω)−R(ω)−Aₒₜₕₑᵣ(ω) by tailoring the transmission T(ω), the reflection R(ω), and the absorption outside the absorbing layer Aₒₜₕₑᵣ(ω). In some embodiments, T(ω), R(ω) and Aₒₜₕₑᵣ(ω) may be minimized for the totality of the energy to be dissipated or absorbed in the absorbing layer 16. In some embodiments, the minimization of T(ω), R(ω) and Aₒₜₕₑᵣ(ω) can be carried out through the selection of the geometry of the PMF layer, as will be described in more details in the Examples section. In general, T(ω), R(ω) and Aₒₜₕₑᵣ(ω) are directly linked to, and thus depend on, the optical parameters permittivity, ∈(ω) or the electric response, and permeability, μ(ω) or the magnetic response, of the PMF layer 14. For the metamaterial effective layer 10 of the present disclosure to be able to operate in a broadband regime, the permittivity and permeability of the PMF layer 14 depend on the frequency (ω) of the electromagnetic wave to be absorbed by the absorbing layer 16 of the present disclosure. This dependency may be achieved by geometric patterning of the PMF layer 14, as is described below.

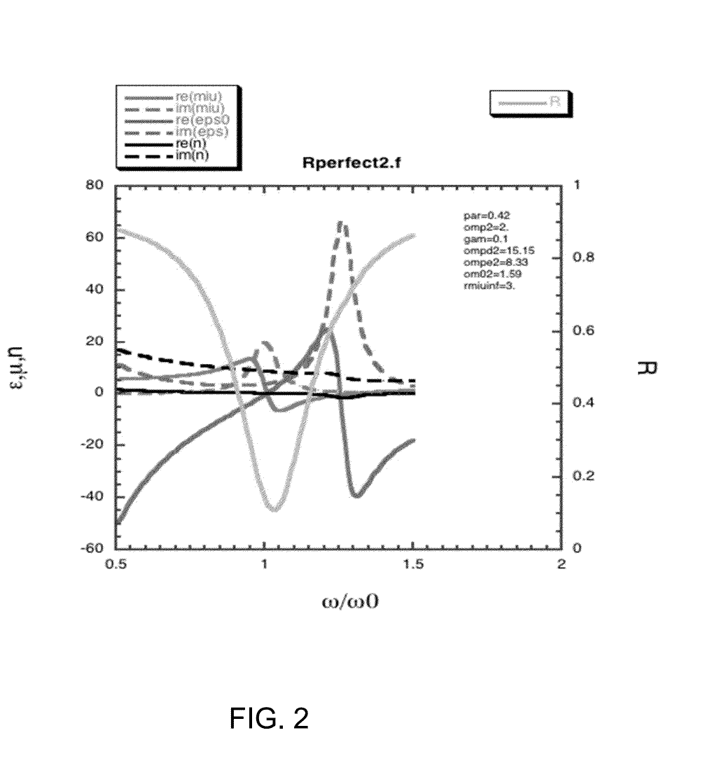

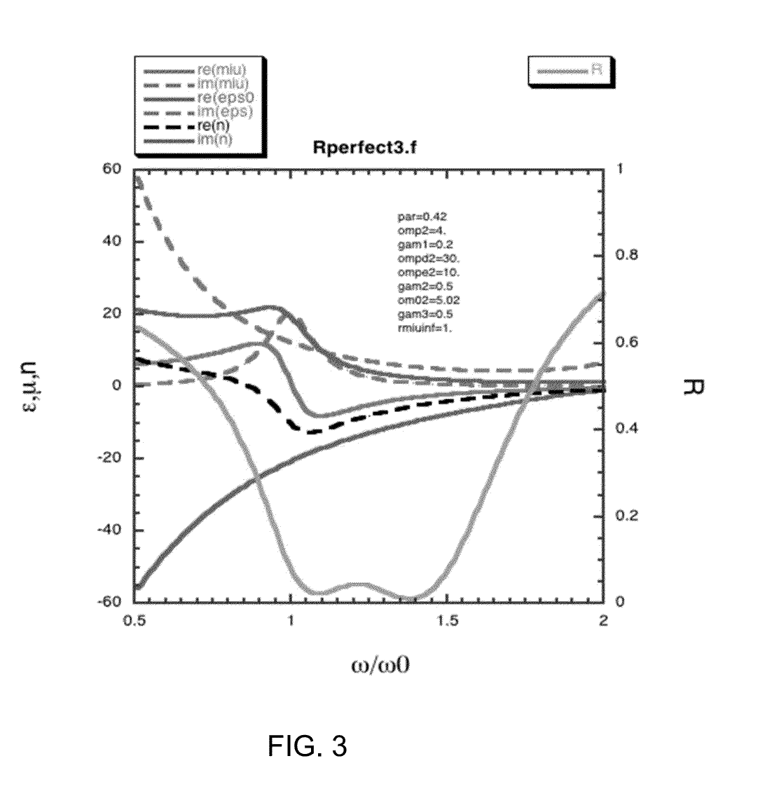

The metamaterial effective layer 10 has an effective, complex dielectric constant and the magnetic susceptibility. A narrow band perfect absorption can be achieved in the metamaterial effective layer 10 by making the metamaterial dielectric constant and the magnetic susceptibility purely imaginary at some frequency, as shown in FIG. 2. In such scenario, reflectivity R is minimum, and thus maximum absorbance (A) of 1-R. On the other hand, the frequency domain can be chosen in which both the metamaterial dielectric constant and the magnetic susceptibility are complex, but with negative real parts. In some embodiments, this can be achieved by focusing on the frequency range immediately above the magnetic resonance and well below the electric resonance (in the Drude tail). As shown in FIG. 3, a strong broadening of the R minimum is observed, which can further be improved by a better choice of parameters and dependencies.

In some embodiments, the PMF layer 14 is patterned with an array of perforations to yield a desired effective ω⁻¹ dependency of ∈_{eff} and μ_{eff}. ω⁻¹ dependency of ∈_{eff} and μ_{eff} means that these parameters are inversely proportional to the frequency of the radiation (1/ω=ω⁻¹). This is unusual dependency, and may require a distinct PMF design. In some embodiments, the array period of perforations ranges between about 100 nm and about 1000 nm. In some embodiments, the array period is subwavelength. In some embodiments, the array period is less than 5000 nm. In some embodiments, the array period is less than 500 nm, less than 400 nm or less than 300 nm. The array may be either periodic or non-periodic. In some embodiments, the perforations 22 can have dimensions between about 70 nm and about 1000 nm. In some embodiments, the perforations 22 can have dimensions in the sub-wavelength limit, i.e. hole diameter is smaller than the received wavelength. In some embodiments, the perforations 22 can have dimensions less than 500 nm, less than 400 nm or less than 300 nm. In some embodiments, the PMF layer 14 comprises an array of metal islands 20. In some embodiments, the metal islands 20 can have dimensions in the sub-wavelength limit. In some embodiments, the metal islands 20 can have dimensions less than 500 nm, less than 400 nm or less than 300 nm. For example, for square metal structures, the sides of the square metal islands can be less than 500 nm, less than 400 nm or less than 300 nm. In some embodiments, the thickness of the PMF layer 14 is subwavelength. In some embodiments, the thickness of the PMF layer 14 is less than 500 nm, less than 400 nm or less than 300 nm. In some embodiments, the thickness of the PMF layer 14 is less than 100 nm. In some embodiments, the thickness of the PMF layer 14 is less than 50 nm or less than 20 nm.

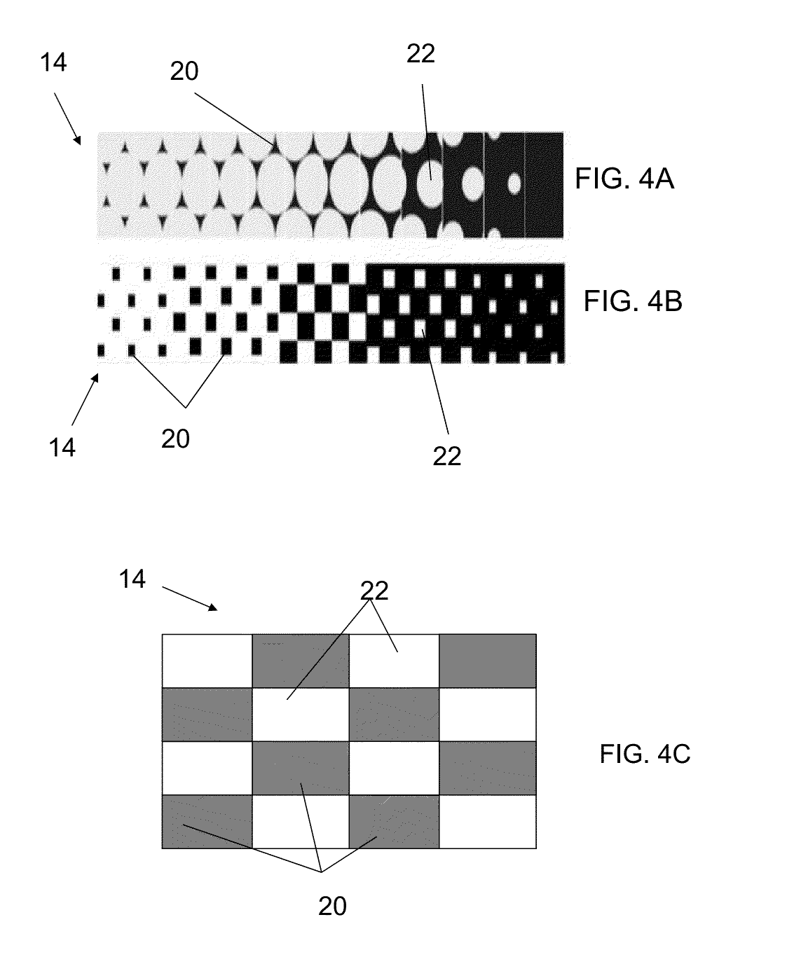

In some embodiments, the shape of the metal islands 20 or perforations 22, their dimensions, and their distribution may be selected so that the structure of the PMF layer 14 is at or near percolation threshold. In some embodiments, the PMF layer 14 may have a percolation threshold structure where periodic structures evolve from an array of islands 20 (on the left hand side) to an array of perforations 20 (on the right hand side), as shown for example in FIG. 4A and FIG. 4B. In some embodiments, the PMF layer 14 may have a checkerboard pattern as shown in FIG. 4C, where metal islands 20 are separated by perforations 22. In some embodiments, the metallic film 14 is a hexagonal array of nearly touching circular perforations 22 (Escheric series). In some embodiments, the PMF layer 14 may have a hexagonal, honeycomb, square, rectangular, triangular or completely random perforations 22 and associated metallic structures 20. Other structures of the PMF layer 14 may be also be used as long as these structures yield a desired effective ω⁻¹ dependency of ∈_{eff} and μ_{eff}. ω⁻¹.

Referring back to FIG. 1, in addition to the metamaterial effective layer 10, the solar cell 1 may further include a interference film 12 disposed on the PMF layer 14. In some embodiments, the interference film 2 may be air. In some embodiments, the interference layer may be an anti-reflective coating (ARC). The ARC layer 12 may be deposited over the metamaterial effective layer 10 and is designed to increase transmittance of light into the absorbing layer 16 by reducing the amount of light that is reflected by the absorbing layer 16 and the PMF layer 14. The ARC coating layer 12 may comprise a single coating layer or multiple coating layers. In some embodiments, the ARC layer 12 is a film of dielectric material. In some embodiments, the ARC layer 12 is an oxide, fluoride, nitride, or sulfide of a metal or metalloid, including, but not limited to, silicon (Si), magnesium (Mg), Zink (Zn), Titanium (Ti), Tin (Sn), Cerium (Ce) and similar materials. Suitable specific examples of suitable anti-reflective coatings include, but not limited to, MgF₂, ZnS, MgF₂, TiO₂, SiO₂, SiNx, CeO₂ and similar materials. Other known and commonly used antireflective coatings may also be used with embodiments disclosed herein. In some embodiments, the thickness of the ARC layer 12 is subwavelength. In some embodiments, the thickness of the ARC layer 12 is less than 100 nm. In some embodiments, the thickness of the ARC layer 12 is less than 50 nm. In some embodiments, the thickness of the ARC layer 12 is less than 500 nm. Detailed design considerations and governing principles for an ARC method suitable for use with the metamaterial effective layer 10 of the present disclosure are discussed in a pending co-owned PCT International Application No. PCT/US2012/044346, entitled “Super-Transparent Electrodes for Photovoltaic Applications,” and filed on Jun. 27, 2012, which application is incorporated herein by reference in its entirety.

Referring back to FIG. 1, the solar cell 1 may further include a rear electrode 18 disposed on the back side of the absorbing layer 16, that is, the side opposite the light absorbing surface of the absorbing layer 16. The rear electrode 18 may be made of a metal, such as, by example, aluminum, gold or another conductive metal. The rear electrode 18, in combination with the PMF layer 14, collects electrical current generated in the absorbing layer 16. The photovoltaic cell 1 may also include a substrate 19, which may provide additional structural support for the photovoltaic cell 1. In some embodiments, the substrate 19 may be made of glass or metal.

### EXAMPLES

Examples (actual and simulated) of using the devices and methods of the present disclosure are provided below. These examples are merely representative and should not be used to limit the scope of the present disclosure. A large variety of alternative designs exist for the methods and devices disclosed herein and are within the spirit and the scope of the present disclosure. The selected examples are therefore used mostly to demonstrate the principles of the methods and devices disclosed herein.

### Example 1

### Theoretical Predictions of Suitable PMF Structures

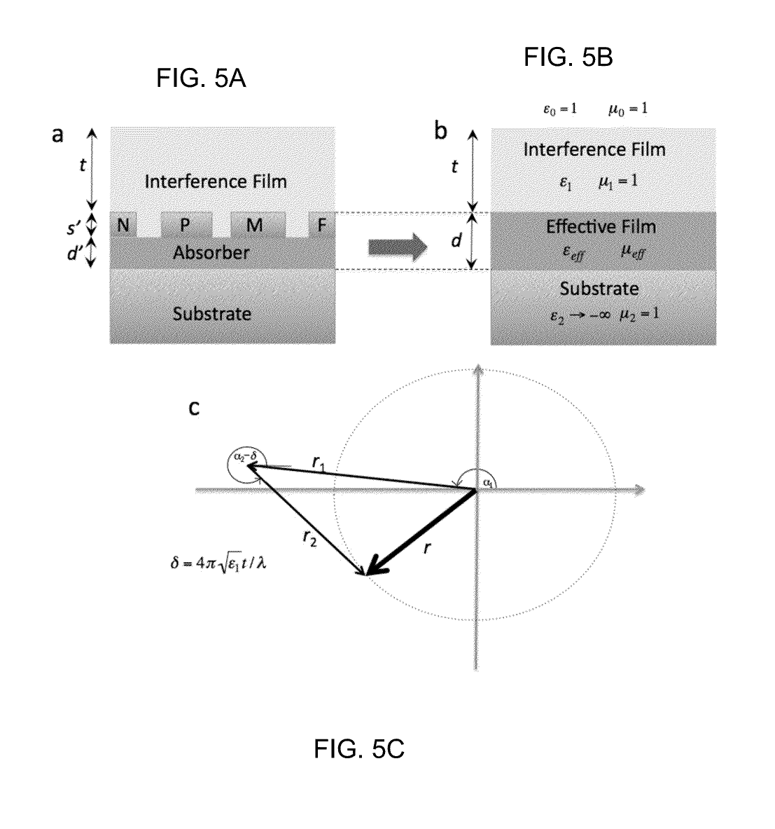

A cross-section of a fragment of the proposed structure is shown schematically in FIG. 5A. It has a basic form of a typical photovoltaic device in a simple planar configuration: a Ag substrate (bottom electrode), an absorber film (the p-i-n junction) of thickness d′, an electrically continuous and nanoscopically perforated metallic film (NPMF) of thickness s′, which acts as a transparent “window” electrode of the cell, and finally an interference film (IF) of thickness t. Reflection suppression is likely in this structure, based on the simplified analysis described below. These conclusions can be confirmed, and the efficiency of a solar cell estimated based on this analysis by employing quantitative first principles simulations.

For d and the NPMF perforation dimensions <<λ (subwavelength limit), one can employ the effective medium model, and represent the structure as a simple planar layer stack shown in FIG. 5B, for which an analytic solution is available. In this stack, the absorber-NPMF pair is represented by a metamaterial effective film (MEF), with ∈_{eff}, μ_{eff}.

By employing the Fresnel method, the total reflection coefficient from the proposed model structure with IF (at normal incidence, at the air-IF interface) is given by

r=f(r₁,r₂,\sqrt{∈₁}t/λ) (1)

r₂=f(−r₁,r₃,0)=|r₂|exp(iα₂) (2)

r₃=f(r_{eff},−1,n_{eff}d/λ) (3)

where the auxiliary function

$$f ( x , y , z ) = \frac{x + y exp ( - i4 π z )}{1 + xy exp ( - i4 π z )} {\approx }_{xy ≪ 1} x + y exp ( - i4 π z ) \qquad ( 4 )$$

In these formulas, r₁ is the Fresnel reflection coefficient for the air-IF interface, given by r₁=(1−\sqrt{∈₁})/(1+\sqrt{∈₁})=|r₁|exp(iα₁), r₂ is the reflection coefficient for the structure at the IF-MEF interface, r₃ is the total reflection coefficient from the structure without IF, and r_{eff}=(1−η)/(1+η) is the Fresnel coefficient at the air-MEF interface. The refractive index of the MEF is n_{eff}=\sqrt{∈_{eff}μ_{eff}} (Im[n_{eff}]>0), and the wave impedance is given by η_{eff}=\sqrt{∈_{eff}/μ_{eff}} (Re[η_{eff}]>0) [Smith, D. R.; Schultz, S.; Markos, P.; Soukoulis, C. M. Phys. Rev. B 2002, 65, 195104.]. In addition to the dielectric function ∈_{eff}, MEF can have a magnetic permeability μ_{eff}≠1, which is a result of the coupling between NPMF and the metallic substrate. A free standing, strictly two dimensional NPMF would have necessarily μ_{eff}=1, since the in-plane magnetic field of the incoming wave cannot induce any currents in the film: the Lorentz force in this case has only a perpendicular (to the film) component. However, in the presence of the metallic substrate, currents can be induced between NPMF and the substrate (via capacitive coupling), which subsequently form closed loops that can lead to nonzero magnetic susceptibility. Since x and y are in general complex, the approximated part of Eq. (4) represents a vector sum of x and y in a complex plane, and then vanishing r according to Eq. (1) requires that the sum of vectors r₁ and r₂ vanishes (see FIG. 5C). Expanding around the wavelength λ₀ at which this vanishing occurs, assuming that r₁ and r₂ are wavelength independent, the reflectance is

R=rr^{*}∝(1−λ₀/λ)² (5)

Numerical evaluation of this equation shows that, surprisingly, the reflectance suppression is broadband, with R<10% in the entire visible range (provided that λ₀ is chosen in the middle of this range). In addition, FIG. 5C shows as follows:

|r₁|+|r|≧|r|₂|≧|r₁|−|r| (6)

This inequality shows that the overall suppression is also tolerant of the specific values of |r₂|. For example, suppressing R below 10%, while employing a typical dielectric with n₁=\sqrt{∈₁}≈2 (i.e., |r₁|≈0.3), requires only that |r₂|<0.6. If r₂ is frequency (ω) independent (or slowly varying), this essential vector cancellation can be always assured by adjusting t, which linearly controls the angle between the two vectors. Thus, a slow r₂ variation with frequency is important for achieving the broadband reflectance suppression in the structure.

According to Eq. (2), r₂ independency on ω follows from independency of r₃ on ω. r₃ is given by Eq. (3), and represents the reflection coefficient of the model structure without the interference film. r₃ is independent on ω only if

∈_{eff} and μ_{eff}∝ω⁻¹ (7)

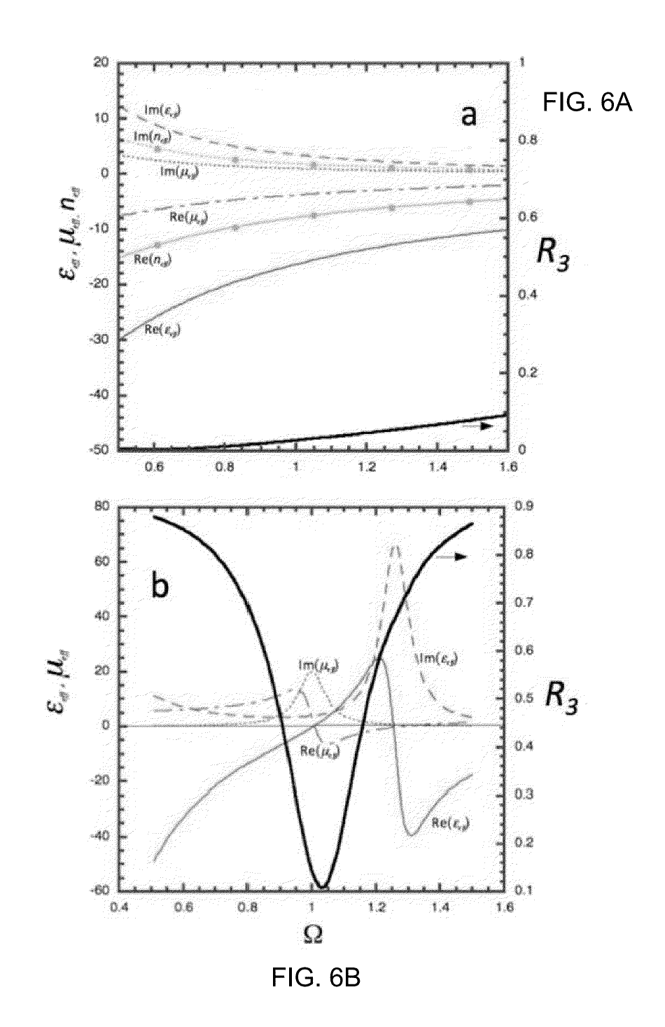

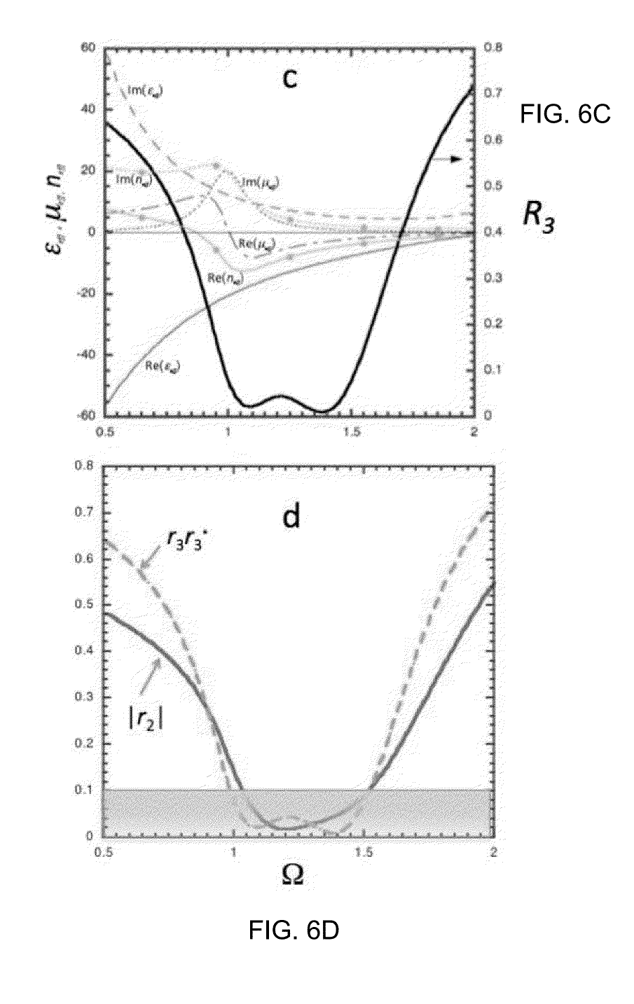

FIG. 6A, FIG. 6B, FIG. 6C, and FIG. 6D present the total reflectance R₃=r₃r₃* vs. normalized frequency Ω=ω/ω₀=6 μm/λ, calculated from Eq. (3) (black bold line), and the corresponding extracted ∈_{eff}, μ_{eff} and n_{eff} for: structure with a modeled response ω⁻¹ (FIG. 6A); structure with resonant (plasmonic) resonances (FIG. 6B); and modified structure with separated plasmonic resonances (FIG. 6C). In FIG. 6D, R₃=r₃r₃* taken from FIG. 6C (dashed line), and the corresponding |r₂| (solid line) obtained from Eq. (2) for the modified structure with separated plasmonic resonances. The shaded region in FIG. 6D is the corresponding range of R<0.1, for this structure with an added interference film; this range is very broad, and exceeds the entire frequency range in this plot.

FIG. 6A shows R₃=r₃r₃*, calculated from Eq. (3) vs. normalized frequency, for the structure of FIG. 5B (but without IF), with ∈_{eff} and μ_{eff} modeled to have the approximate ω⁻¹ dependency:

$$A - \frac{B}{ω + i γ} ,$$

where A, B, and γ are constant. Plotted are also the corresponding ∈_{eff}, μ_{eff}, and n_{eff}. The resulting R₃ is small (<10%) in a very broad frequency range, as expected. The broadband suppression of R follows. Note, that for vanishing r₃, r₂≈−r₁ and finally r≈r₁−r₁ exp(−i4 π\sqrt{∈₁}t/λ), which vanishes if λ₀=2\sqrt{∈₁}t. This action of IF resembles that of the usual anti-reflection coating (ARC) [Heavens, O. S. Optical properties of thin solid films. Dover Publications, Inc.; New York, 1965.], except for different λ₀. Eq. (5) thus holds, assuring a broadband suppression of R as well, even if r₃ is not very small.

The ω⁻¹ dependency of ∈_{eff} and μ_{eff} is unusual for an effective medium (in fact this for cannot be correct in the entire frequency range, since it violates the f-sum rule). FIG. 6B shows R₃ for a structure with the usual dependency of ∈_{eff} and μ_{eff} (Kempa, K. Phys. Rev. B 2006, 74, 033411.): sum of Lorentzian terms, each representing a localized plasmonic resonance (e.g., electric Mie resonance)

$$A + \sum \frac{B}{C - ω ( ω + i γ )} ,$$

where A, B, C, and γ are constant. In contrast to FIG. 6A, the reflectance suppression occurs now in a very narrow band. The model parameters have been adjusted to represent the structure in which such narrow band super-absorption (R very close to 0) was recently demonstrated, both by simulations and experiments (Hao, J.; Wang, J.; Liu, X.; Padilla, W. J.; Zhou, L.; Qiu, M. Appl. Phys. Let. 2010, 96, 251104.). In this structure the reflectance suppression relies on a strong interaction between the magnetic and electric resonances in the effective film; note that in this case (see FIG. 5B) the two resonances are very close together, and the minimum of R₃ occurs at the normalized frequency Ω≈1, which is simultaneously the de-localized electric bulk plasmon frequency (Re[∈_{eff}]=0), and the localized magnetic plasmon frequency (Im[μ_{eff}]=maximum). The resonant character of the reflectance suppression comes directly from the resonant character of this plasmonic interaction.

The ω⁻¹ dependency, required for the broadband operation, can approximately occur only in properly engineered structures, and in a limited frequency band away from these plasmonic resonances. To test this idea, the model parameters were changed leading to FIG. 6B, by substantially increasing the C parameter in ∈_{eff}, i.e., by blue-shifting the electric plasmonic resonance, away from the magnetic resonance (still at Ω≈1). The de-localized electric bulk plasmon occurs at Ω≈2.2. Thus, a window opens up in-between these resonances, in which both ∈_{eff} and μ_{eff} monotonically decay, resembling the ω⁻¹ dependency, as shown in FIG. 6C. The resulting R₃, also shown in this figure, is suppressed in a much broader band as expected, and in a non-resonant region. Re(n_{eff}) is negative in the window, indicating that the structure is a negatively refracting (left-handed) metamaterial in this frequency range. The same happens for the case shown in FIG. 6A. This is related to the fact, that the coexistence of propagating bulk and surface plasmon modes in the effective film is required to facilitate an efficient reflectance suppression.

The presence of the IF film helps to broaden this response further. The corresponding |r₂| from Eq. (2) was calculated. FIG. 6D shows both, R₃=r₃r₃*, and |r₂|. While R₃ is suppressed to below 10% only in a relatively narrow band (1<Ω<1.5), |r₂| is less than 0.6 in the entire frequency range shown, and beyond. Thus, as discussed below the inequality (6), this assures less than 10% overall reflectance R in this very broad frequency range (see the shaded region in FIG. 6D), i.e., much broader super-absorption band than that of the structure alone, without the interference film.

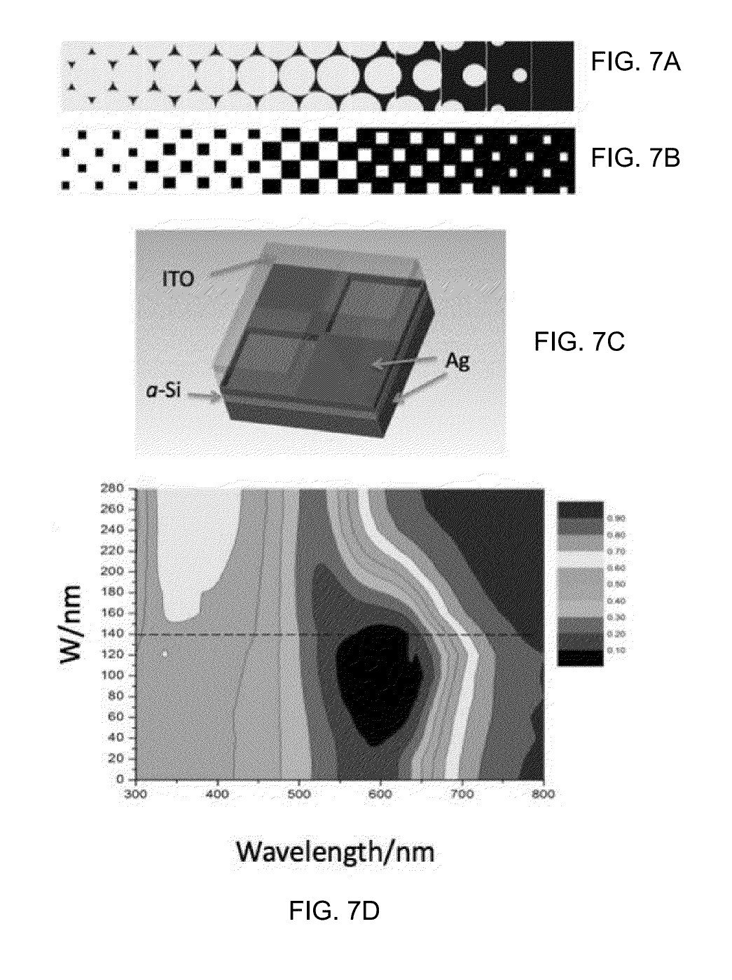

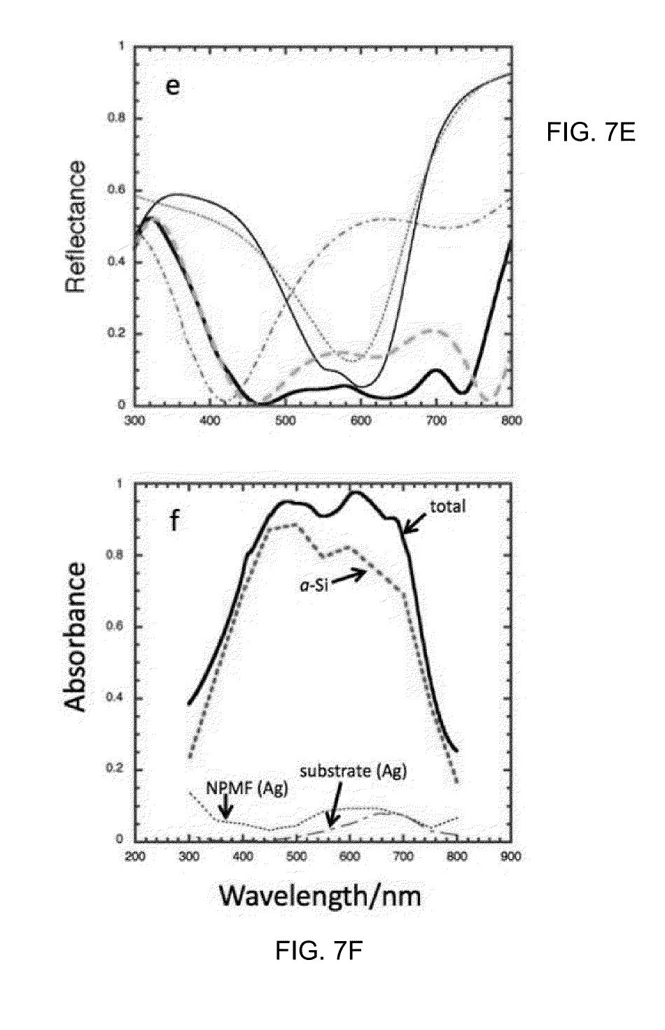

The key task is to discover a specific NPMF structure, which will yield the desired effective ω⁻¹ dependency of ∈_{eff} and μ_{eff}, at least approximately. A good candidate is a percolation threshold structure from a series of periodic structures evolving from islands to holes, as shown in FIGS. 3a and 3b. This evolution is an analog of the percolation problem (Peng, Y.; Paudel, T.; Chen, W.-C.; Padilla, W. J.; Ren, Z. F.; Kempa, K. Appl. Phys. Letters 2010, 97, 041901.; Kempa, K. Phys. Status Solidi (RRL) 2010, 4, 218-220.; Bergman, D. J.; Imry, Y. Phys. Rev. Lett. 1977, 39, 1222-1225.), and thus it is singular/critical at the percolation threshold pattern (Bergman, D. J.; Imry, Y. Phys. Rev. Lett. 1977, 39, 1222-1225). The effective dielectric function of such structures consists of, as discussed above, electric and magnetic plasmonic resonances. These resonances at the percolation threshold rapidly shift away from their original frequency locations, leaving a smoothly varying ∈_{eff} and μ_{eff}, which resemble the required ω⁻¹ dependency. A particularly singular series of structures is generated from the checkerboard pattern (Kempa, K. Phys. Status Solidi (RRL) 2010, 4, 218-220) (percolation pattern of this series) by uniformly changing the sizes of the checkerboard squares (W×W), but leaving the checkerboard period unchanged, as shown in FIG. 7B. The patterns to the right and left of the checkerboard pattern form Babinet complementary pairs (Jackson, J. D. Classical Electrodynamics, 3rd ed. John Wiley & Sons Ltd.; New York, 1998), and that the checkerboard pattern itself is a self-Babinet complementary structure. It was shown (Kempa, K. Phys. Status Solidi (RRL) 2010, 4, 218-220.), that the checkerboard pattern can be represented by an effective thin film, with ∈_{eff}˜ω⁻¹, the ideal dependency for the broadband super-absorbance. In the present structure configuration, the NPMF would be designed to be not far from the percolation threshold pattern (checkerboard), and thus μ_{eff} should at least be smoothly varying. Thus, the checkerboard pattern may be a good candidate for the NPMF.

### Example 2

### Computer Simulation Using Suitable PMF Structures

A series of computer simulations for the original (not simplified) structure verify theoretical predictions above, schematically shown in FIG. 5A, with the checkerboard series structures as NPMF. These simulations are based on the high accuracy finite-difference time-domain (FDTD) and finite-difference frequency-domain (FDFD) methods (Taflove, A. Computational Electrodynamics: The Finite-Difference Time-Domain Method. Artech House; Norwood, Mass., 1995. Wang, X.; Kempa, K. Phys. Rev. B 2005, 71, 233101). The following computer software was employed: CST Microwave Studio from the Computer Simulation Technology AG (http://www.cst.com/), and the MEEP from Massachusetts Institute of Technology (http://ab-initio.mit.edu/wiki/index.php/Meep). These have been shown to be quantitative in predicting the performances of nano-optical structures.

These methods identify an optimized structure, unit cell of which is shown in FIG. 7C. Since the NPMF period is a=280 nm and w=145 nm, the pattern is close to the checkerboard, but on the conducting side of the percolation threshold. This allows NPMF to act also as a highly conducting top electrode of a solar cell with a sheet resistance of <10Ω/γ. Published experimental data (Data for Ag: D. Palik, Handbook of Optical Constants of Solids. Academic Press; Boston, 1985. Data for a-Si and ITO: Sopralab basic n&k files database (http://www.sopra-sa.com/index.php)) were used for all dielectric functions. The optimized absorber thickness is only 15 nm. FIG. 7E shows the simulated reflectance for this optimized structure (bold-solid black line). Indeed, the reflectance suppression is excellent in the entire useful band for the a-Si absorber (400-800 nm).

For comparison, FIG. 7E shows also reflectance for other related structures. The thin-dotted red line is for a structure consisting of only the substrate and the absorber, and as expected it shows very narrow and relatively inefficient reflectance suppression. The thin dashed-dotted red line is for this structure with the IF added. There does not appear to be an improvement of the bandwidth, but instead a blue shift of the minimum. The thin-solid black line is for the structure consisting of the substrate, absorber and the NPMF (but no IF). The reflectance suppression appears broader than that for the structure without NPMF, but still relatively narrow. This changes dramatically (almost threefold increase of the bandwidth) after the IF is added to this structure, yielding the optimized structure discussed above. In addition, a dashed-bold green line represents a result for a complete structure (all films), but with much larger period of the checkerboard (a=750 nm, w=390 nm). It also shows a very broad reflectance suppression, however less efficient than that for the optimal structure. This, on one hand, illustrates that the subwavelength geometry may be preferred in this effect, but on the other, it shows that even outside the subwavelength regime (W˜λ), the band of the suppressed reflectance remains very broad.

FIG. 7D, shows the color-encoded map of R vs. W and λ. It confirms that the suppression bandwidth indeed maximizes not far from the percolation threshold pattern (for W≈120 nm). This band broadening at the percolation threshold can be understood as follows. The structures on either side of the threshold are arrays of discrete elements (islands above the threshold, where W<140 nm, and holes below, where W>140 nm). These have, as discussed above, localized, narrow band plasmonic resonances. Sufficiently far from the percolation threshold these are degenerate, and thus the effective response is narrowband. At the threshold the inter-island or inter-hole interactions remove the degeneracy, shifting and broadening the resonances. This is somewhat similar to formation of electronic bands in solids from hybridized electronic levels of individual atoms. However, while the usual band formation effects in solids are short range, and thus well described by the tight-binding type of analysis, the interactions near the percolation threshold became critical, i.e., long-range. The fact that the maximum of the bandwidth occurs for W<140 nm (i.e., slightly away from the checkerboard pattern) is in fact expected, and result of interaction of the NPMF with the metallic substrate. This explanation of the band broadening should hold for other percolation threshold structures. To check this, the checkerboard NPMF was replaced with the structures near the percolation threshold of the series shown in FIG. 7A, with similar dimensions. The simulations for this case showed a less efficient R suppression, in a narrower band, and a much less pronounced maximization of the bandwidth at the percolation threshold. Also, after addition of the IF coating, the suppression band remained much narrower than that for the optimized checkerboard structure. This points to the checkerboard, as a possible preferred NPMF structure.

The reflection suppression in the optimized structure is excellent, and is due to absorption. Furthermore, this absorption can be engineered to be overwhelmingly in the absorber (a-Si), and not in the metal (Ag). To show that, further simulations were performed for the optimized structure with lossless IF (e.g., lossless ITO), and with best bulk quality Ag (Johnson, P. B. and Christy, R. W. Phys. Rev. B 1972, 6, 370.), recently demonstrated experimentally with nanoscopically thin films (Chen, W., Thoreson, M. D., Ishii, S., Kildishev, A. V., and Shalaev, V. M., Optics Express 2010, 18, 5124). FIG. 7F shows the total absorbance, as well as the partial absorbances in the absorber, and Ag layers (NPMF and substrate). IF is made of the lossless ITO ∈_{ITO}=3.8), and the dielectric function of Ag is taken from Kempa, K.; Naughton, M. J.; Ren, Z. F.; Herczynski, A.; Kirkpatrick, T.; Rybczynski, J.; Gao, Y. Appl. Phys. Lett., 2009, 95, 233121). It appears that the absorbance in the a-Si absorber dominates.

To estimate the potential photovoltaic performance of the structure the absorbance in the a-Si only was used, as shown in FIG. 7F (bold-dotted line). This absorbance, which with high-quality p-i-n junctions is essentially identical to the external quantum efficiency (Springer, J.; Poruba, A.; Vanecek, M. Journal of Applied Physics 2004, 96, 5329.), can be integrated (Krc, J.; Smole, F.; Topic, M. Prog. Photovolt: Res. Appl. 2003, 11, 15.) with the solar power spectrum (AM 1.5) to yield the expected short circuit current density J_{sc}, an important parameter of solar cells. A record high J_{sc}=19.7 mA/cm² was obtained, much higher than J_{sc}=17 mA/cm² of the present efficiency champion single junction a-Si solar cell (Meier, J.; Spitznagel J.; Kroll, U.; Bucher, C.; Faÿ, S.; Moriarty, T.; Shah, A. Thin Solid Films, 2004, 451-452, 518-524). Experimental results with ultra-thin, planar a-Si p-i-n junctions, show that these indeed can be of excellent quality (Krc, J.; Smole, F.; Topic, M. Prog. Photovolt: Res. Appl. 2003, 11, 15). For example (Kempa, K.; Naughton, M. J.; Ren, Z. F.; Herczynski, A.; Kirkpatrick, T.; Rybczynski, J.; Gao, Y. Appl. Phys. Lett., 2009, 95, 233121), an un-optimized junction with p, i, n layers of 5, 10, 5 nm in thickness, respectively, achieved a fill factor FF=0.7, and an open circuit voltage V_{oc}=0.87 V, at much lower current density of 4.6 mA/cm² due to inefficient light absorption. It was also demonstrated that these ultra-thin (<5 nm) p and n layers strongly contribute to the generated photocurrent (Krc, J.; Smole, F.; Topic, M. Prog. Photovolt: Res. Appl. 2003, 11, 15.). Using parameters of these junctions with the simulated current density J_{sc}=19.7 mA/cm² yields a conservatively estimated efficiency of 12%. With further optimization of such ultra-thin junctions, 15% efficiency of the structure is possible.

In some embodiments, a metamaterial structure includes a light absorbing layer capable of absorbing solar energy and converting the absorbed energy into electrical current, a patterned metallic film disposed on a light absorbing surface of the light absorbing layer, the patterned metallic film being configured to increase light absorption in the light absorbing layer.

In some embodiments, a photovoltaic cell includes a light absorbing layer capable of absorbing solar energy and converting the absorbed energy into electrical current, a patterned metallic film disposed on a light absorbing surface of the light absorbing layer, the patterned metallic film being configured to increase light absorption in the light absorbing layer, and a rear electrode disposed on a surface of the absorbing layer opposite to the light absorbing surface of the light absorbing layer, wherein the rear electrode and the patterned metallic film are in electrical communication with the absorbing layer to collect electrical current generated in the light absorbing material.

In some embodiments, a method for increasing efficiency of a solar cell includes disposing a patterned metallic film on a light absorbing surface of a light absorbing layer, wherein the light absorbing layer is capable of absorbing solar energy and converting the absorbed energy into electrical current; disposing a rear electrode on a surface of the absorbing layer opposite to the light absorbing surface of the light absorbing layer; exposing the light absorbing layer to light, and collecting electrical current generated in the absorbing layer from the absorbed light.

In some embodiments, a photovoltaic cell includes a light absorbing layer capable of absorbing solar energy and converting the absorbed energy into electrical current; a perforated conductive film disposed on a light absorbing surface of the light absorbing layer, the conductive film being configured to increase light absorption in the light absorbing layer; and a rear electrode disposed on a surface of the absorbing layer opposite to the light absorbing surface of the light absorbing layer, wherein the rear electrode and the conductive film are in electrical communication with the absorbing layer to collect electrical current generated in the light absorbing material.

In some embodiments, an absorbing layer for a solar cell includes a light absorbing layer capable of absorbing solar energy and converting the absorbed energy into electrical current; and a perforated conductive film disposed on a light absorbing surface of the light absorbing layer, the conductive film being configured to increase light absorption in the light absorbing layer.

In some embodiments, a method for forming a solar cell includes positioning a perforated conductive film disposed on a light absorbing surface of a light absorbing layer, wherein the light absorbing layer is capable of absorbing solar energy and converting the absorbed energy into electrical current and the conductive film is configured to increase light absorption in the light absorbing layer; disposing a rear electrode on a surface of the absorbing layer opposite to the light absorbing surface of the light absorbing layer; and configuring the rear electrode and the perforated conductive film to collect electrical current generated in the light absorbing layer.

All patents, patent applications, and published references cited herein are hereby incorporated by reference in their entirety. While the devices and methods of the present disclosure have been described in connection with the specific embodiments thereof, it will be understood that they are capable of further modification. Furthermore, this application is intended to cover any variations, uses, or adaptations of the devices and methods of the present disclosure, including such departures from the present disclosure as come within known or customary practice in the art to which the devices and methods of the present disclosure pertain, and as fall within the scope of the appended claims.

What is claimed is:

1. A photovoltaic cell comprising:
a light absorbing layer capable of absorbing solar energy and converting the absorbed energy into electrical current;
a perforated conductive film disposed on a light absorbing surface of the light absorbing layer, the conductive film being configured to increase light absorption in the light absorbing layer; and
a rear electrode disposed on a surface of the absorbing layer opposite to the light absorbing surface of the light absorbing layer, wherein the rear electrode and the conductive film are in electrical communication with the absorbing layer to collect electrical current generated in the light absorbing material.

2. The photovoltaic cell of claim 1 wherein the light absorbing layer is a p-i-n photovoltaic junction.

3. The photovoltaic cell of claim 1 wherein the light absorbing layer is a p-n photovoltaic junction.

4. The photovoltaic cell of claim 1 wherein the conductive film is less than about 500 nm in thickness.

5. The photovoltaic cell of claim 1 wherein the conductive film is patterned with an array of perforations.

6. The photovoltaic cell of claim 5 wherein the array period is between about 100 nm and 1000 nm.

7. The photovoltaic cell of claim 5 wherein the perforations are less than 500 nm.

8. The photovoltaic cell of claim 1 wherein the conductive film is patterned with an array of conductive islands.

9. The photovoltaic cell of claim 8 wherein all dimensions of the conductive islands are less than 500 nm.

10. The photovoltaic cell of claim 1 wherein the conductive film has a structure evolving from conductive islands to perforations.

11. The photovoltaic cell of claim 1 wherein the conductive film has a structure at or near percolation threshold.

12. An absorbing layer for a solar cell comprising:
a light absorbing layer capable of absorbing solar energy and converting the absorbed energy into electrical current; and
a perforated conductive film disposed on a light absorbing surface of the light absorbing layer, the conductive film being configured to increase light absorption in the light absorbing layer.

13. The absorbing layer of claim 12 wherein the conductive film is less than about 500 nm in thickness.

14. The absorbing layer of claim 12 wherein the conductive film is patterned with an array of perforations with the array period is between about 100 nm and 1000 nm and the perforations being less than 500 nm.

15. The absorbing layer of claim 12 wherein the conductive film is patterned with an array of conductive islands having all dimensions of less than 500 nm.

16. A method for forming a solar cell comprising:
positioning a perforated conductive film disposed on a light absorbing surface of a light absorbing layer, wherein the light absorbing layer is capable of absorbing solar energy and converting the absorbed energy into electrical current and the conductive film is configured to increase light absorption in the light absorbing layer;
disposing a rear electrode on a surface of the absorbing layer opposite to the light absorbing surface of the light absorbing layer; and
configuring the rear electrode and the perforated conductive film to collect electrical current generated in the light absorbing layer.

17. The method of claim 16 wherein the light absorbing layer is a photovoltaic junction material.

18. The method of claim 16 wherein the conductive film is less than about 500 nm in thickness.

19. The method of claim 16 wherein the conductive film is patterned with an array of perforations with the array period is between about 100 nm and 1000 nm and the perforations being less than 500 nm.

20. The method of claim 16 wherein the conductive film is patterned with an array of conductive islands having all dimensions of less than 500 nm.
